(19) United States
(12) Patent Application Publication
(10) Pub. No.: US 2016/0093604 A1
(43) Pub. Date: Mar. 31, 2016

(54) SEMICONDUCTOR DEVICE

(71) Applicant: KABUSHIKI KAISHA TOSHIBA, Tokyo (JP)

(72) Inventor: Hideaki SAI, Ibo Hyogo (JP)

(21) Appl. No.: 14/637,128

(22) Filed: Mar. 3, 2015

(30) Foreign Application Priority Data
Sep. 25, 2014 (JP) 2014-194739

(51) Int. Cl. H01L 27/02; H01L 29/06; H01L 23/522; H01L 29/861; H01L 29/866; H01L 29/36; H01L 23/528

(52) U.S. Cl. CPC H01L 27/0255; H01L 29/36; H01L 29/0688; H01L 23/528; H01L 29/861; H01L 29/866; H01L 23/5222

(57) ABSTRACT

A semiconductor device includes a first semiconductor region of a first conductivity type, a second semiconductor region of a second conductivity type selectively provided on a surface of the first semiconductor region, an insulating layer provided on the first semiconductor region and on the second semiconductor region, and having a first opening exposing a portion of the second semiconductor region therein, a wiring layer on the insulating layer and electrically connected to the second semiconductor region through the first opening, and a third semiconductor region of the second conductivity type below the insulating layer and contacting the first semiconductor region.

### CROSS-REFERENCE TO RELATED APPLICATION

This application is based upon and claims the benefit of priority from Japanese Patent Application No. 2014-194739, filed Sep. 25, 2014, the entire contents of which are incorporated herein by reference.

### FIELD

Embodiments described herein relate generally to a semiconductor device.

### BACKGROUND

In a semiconductor device mounted on an electronic apparatus, an electronic system, and the like, there is an electrostatic discharge (ESD) protective diode for protecting an internal circuit against static electricity applied from the exterior of the device to a signal terminal of the device. As a high frequency signal flows in the internal circuit to be protected, low capacitance of the ESD protective diode is required. Furthermore, the size ratio of an electrode pad provided on a surface of the semiconductor device and the semiconductor device has increased as semiconductor devices have become smaller. An interlayer insulation film is provided between the electrode pad and a semiconductor layer. The electrode pad is connected to the semiconductor layer through an opening provided in the interlayer insulation film.

However, the interlayer insulation film provided between the electrode pad and the semiconductor layer becomes a factor in the generation of parasitic capacitance. As a method for decreasing the parasitic capacitance, there is a method of increasing a thickness of the interlayer insulation film. However, if the thickness of the interlayer insulation film is increased, an aspect ratio of the opening of the interlayer insulation film is also increased and step coverage of an electrode terminal formed inside the opening is worsened. Thus, a technique for decreasing the parasitic capacitance of the semiconductor device is required irrespective of the method of increasing the thickness of the interlayer insulation film.

### DESCRIPTION OF THE DRAWINGS

FIG. 1A is a schematic cross-sectional view illustrating a portion of a semiconductor device according to a first embodiment, and FIG. 1B is an enlarged view of the region of FIG. 1A surrounded by the broken line P of FIG. 1A.

FIG. 2 is a schematic cross-sectional view illustrating a portion of a semiconductor device according to a reference example.

FIG. 3A is a schematic cross-sectional view illustrating a portion of a semiconductor device according to a second embodiment, taken along each line A-A′ of FIGS. 3B, 3C, and 3D, and FIGS. 3B, 3C, and 3D are schematic plan views along a surface cut along line B-B′ of FIG. 3A viewed from above.

FIG. 4 is a schematic cross-sectional view illustrating a portion of a semiconductor device according to a third embodiment.

FIG. 5A is a schematic plan view illustrating a portion of a semiconductor device of a fourth embodiment, FIG. 5B is an equivalent circuit diagram of the semiconductor device according to the fourth embodiment, and FIG. 5C is a schematic cross-sectional view illustrating a portion of the semiconductor device according to the fourth embodiment and illustrating a cross section taken along line D-D′ in FIG. 5A.

FIG. 6 is a schematic enlarged cross-sectional view of a lower portion of an insulating layer of the semiconductor device according to the fourth embodiment.

### DETAILED DESCRIPTION

An object of exemplary embodiments is to provide a semiconductor device in which a parasitic capacitance is decreased.

In general, according to one embodiment, a semiconductor device includes: a first semiconductor region of a first conductivity type; a second semiconductor region of a second conductivity type selectively provided on a surface of the first semiconductor region; an insulating layer provided on the first semiconductor region and on the second semiconductor region, and having a first opening exposing a portion of the second semiconductor region therein; a wiring layer on the insulating layer and electrically connected to the second semiconductor region through the first opening; and a third semiconductor region of the second conductivity type below the insulating layer and contacting the first semiconductor region.

Hereinafter, an embodiment will be described with reference to the drawings. In the following description, the same reference numerals are given to the same elements throughout the drawing figures, and description of the features will not be repeated as appropriate.

### First Embodiment

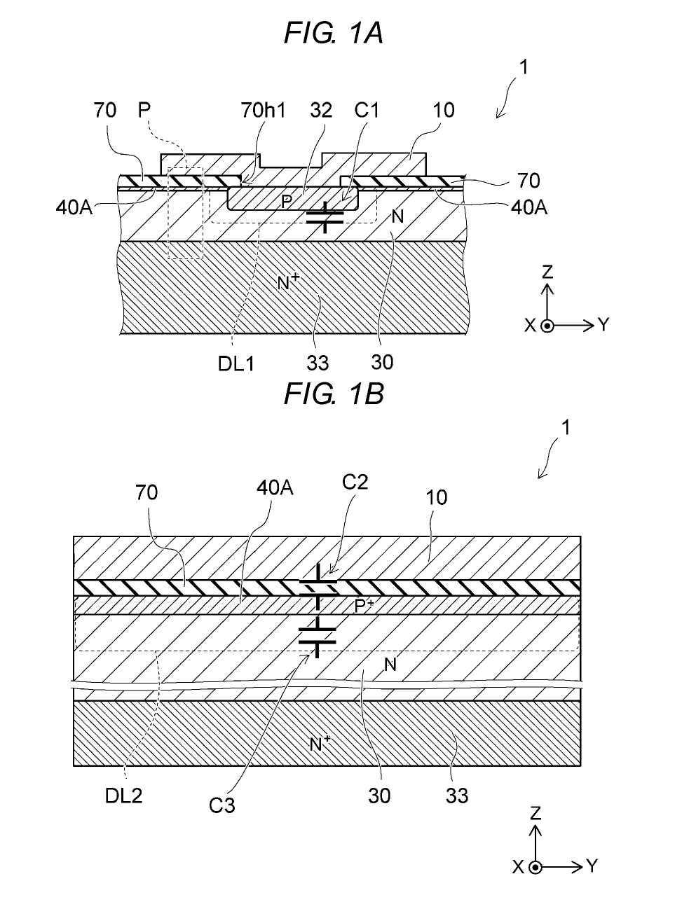

FIG. 1A is a schematic cross-sectional view illustrating a portion of a semiconductor device according to a first embodiment, and FIG. 1B is an enlarged cross sectional view of a region surrounded by the broken line P shown FIG. 1A.

A semiconductor device 1 according to the first embodiment is a Land Grid Array (LGA) type semiconductor chip including an electrode pad (hereinafter, for example, a wiring layer 10) having a relatively large area on a surface side of the semiconductor device 1.

The semiconductor device 1 includes an N-type first semiconductor region (hereinafter, for example, a semiconductor region 30), a P-type second semiconductor region (hereinafter, for example, a semiconductor region 32), a P⁺-type third semiconductor region (hereinafter, for example, a semiconductor region 40A), an insulating layer 70 having a first opening (hereinafter, for example, an opening 70h1), and the wiring layer 10.

The semiconductor region 32 is selectively provided on, and extending inwardly of the surface of, the semiconductor region 30. The semiconductor region 30 comes into contact with the semiconductor region 32 to form a PN diode at the interfacial contacting surfaces (junction) of the P-type semiconductor region 32 and the N-type semiconductor region 30. The insulating layer 70 is provided on the semiconductor region 30 and on a portion of the semiconductor region 32. In the first embodiment, an N-type semiconductor region 30 is illustrated as an example and the semiconductor device 1 is described. In the first embodiment, a P-type semiconductor region 32 is illustrated as an example and the semiconductor device 1 is described.

The insulating layer 70 has an opening 70h1 exposing a part of the semiconductor region 32 therein. The wiring layer 10 is provided on the insulating layer 70. The wiring layer 10 is connected to the semiconductor region 32 through the opening 70h1 of the insulating layer 70. For example, the wiring layer 10 is formed by a sputtering method. The semiconductor region 32 comes into ohmic contact with the wiring layer 10.

The semiconductor region 40A is provided below the insulating layer 70. The semiconductor region 40A comes into contact with the semiconductor region 30 and with the insulating layer 70. The semiconductor region 40A has, for example, a floating potential. A potential lower than a potential of the semiconductor region 30 may be applied to the semiconductor region 40A. If a potential lower than the potential of the semiconductor region 30 is applied to the semiconductor region 40A, reverse bias is applied to the PN junction formed at the junction of the first semiconductor region 30 and the second semiconductor region 32, and the extension of a depletion layer along the junction between the P-type semiconductor region 32 and the N-type semiconductor region 30 may be adjusted by the potential thereof.

An operation of the semiconductor device 1 will be described.

The semiconductor device 1 is formed with a depletion layer DL1 by a diffusion potential caused by the junction between the P-type semiconductor region 32 and the N-type semiconductor region 30 (region inside a broken line of FIG. 1A). The semiconductor device 1 includes a junction capacitance C1 of the semiconductor region 32/the depletion layer DL1/the semiconductor region 30. The junction capacitance becomes a parasitic capacitance in the semiconductor device 1.

Furthermore, the semiconductor device 1 is provided with the semiconductor region 40A below, and insulated from, the wiring layer 10. Thus, a depletion layer DL2 is also formed by the diffusion potential caused by the junction between the semiconductor region 40A and the N-type semiconductor region 30 (region inside a broken line P of FIG. 1B).

Thus, in a region of the device 1 in which the semiconductor region 40A is provided, a capacitance in which a parasitic capacitance C2 formed by the wiring layer 10/the insulating layer 70/the semiconductor region 40A and a junction capacitance C3 formed by the semiconductor region 40A/the depletion layer DL2/the semiconductor region 30 are connected in series become a parasitic capacitance.

Here, a thickness of the depletion layer DL2 is made thicker than a thickness of the insulating layer 70 by adjusting an impurity concentration of the semiconductor region 40A or an impurity concentration of the semiconductor region 30. Thus, the parasitic capacitance C2 becomes smaller than the junction capacitance C3. Thus, a parasitic capacitance C_{L} in which the parasitic capacitance C2 and the junction capacitance C3 are connected in series may be approximated to substantially to C3 from the following Expression (1). That is, the parasitic capacitance C_{L} becomes C3 that is a substantially small capacitance. Thus, the parasitic capacitance in the semiconductor device 1 becomes a capacitance in which the junction capacitance C1 and the small parasitic capacitance C_{L} are connected in parallel.

1/C_{L}=(1/C2)+(1/C3) (1)

As described above, it is possible to decrease the parasitic capacitance of the semiconductor device 1 by providing the semiconductor region 40A below the wiring layer 10.

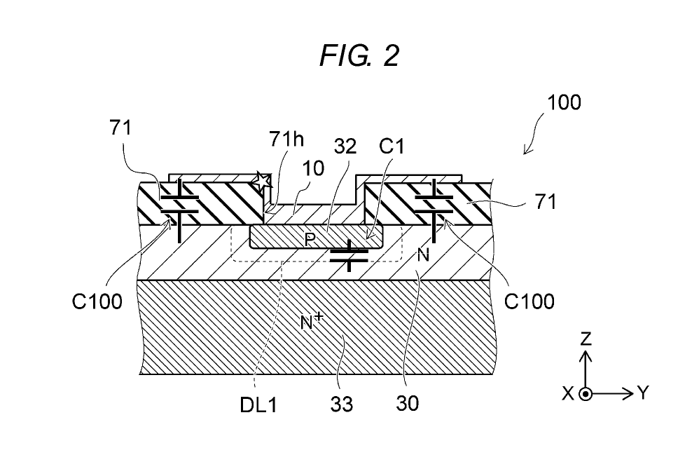

FIG. 2 is a schematic cross-sectional view illustrating a portion of a semiconductor device according to a reference example.

As a method for decreasing the parasitic capacitance of the semiconductor device, there is a method of increasing the thickness of the insulating layer 70. The method is illustrated in FIG. 2.

Also in the semiconductor device 100 of the reference example, the junction capacitance C1 is generated by the semiconductor region 32/the depletion layer DL1/the semiconductor region 30. However, a thickness of an insulating layer 71 of the semiconductor device 100 of the reference example is thicker than the thickness of the insulating layer 70 of the semiconductor device 1. Thus, a parasitic capacitance C100 formed by the wiring layer 10/the insulating layer 71/the semiconductor region 30 is smaller than the parasitic capacitance C2 of the semiconductor device 1. It is also possible to decrease the parasitic capacitance of the semiconductor device by such a structure. Thus, the parasitic capacitance in the semiconductor device 100 becomes a capacitance in which the junction capacitance C1 and the small parasitic capacitance C100 are connected in parallel.

However, if the thickness of the insulating layer 71 is thick, an aspect ratio of an opening 71h of the insulating layer 71 is increased. Thus, step coverage of the wiring layer 10 inside the opening 71h is deteriorated. As a result, the portion of the wiring layer 10 in the opening 71h may become disconnected from the portion thereof extending over the insulating layer and an open defect may occur in the semiconductor device.

In contrast, in the semiconductor device 1 of the first embodiment, it is possible to decrease the parasitic capacitance of the semiconductor device without increasing the thickness of the insulating layer 70.

### Second Embodiment

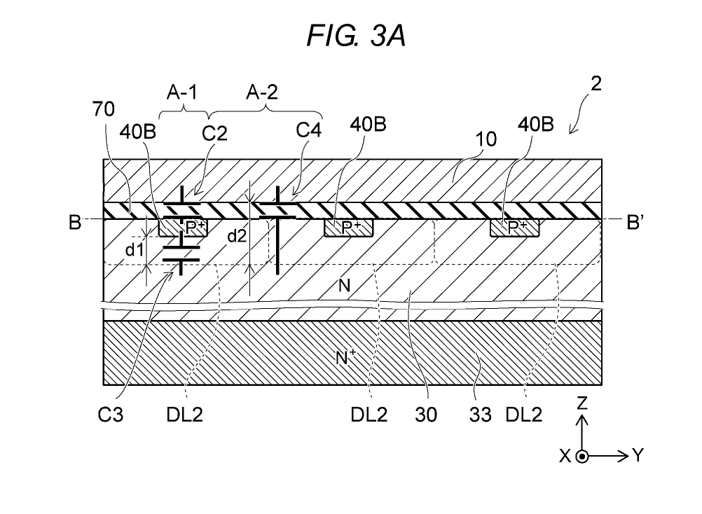

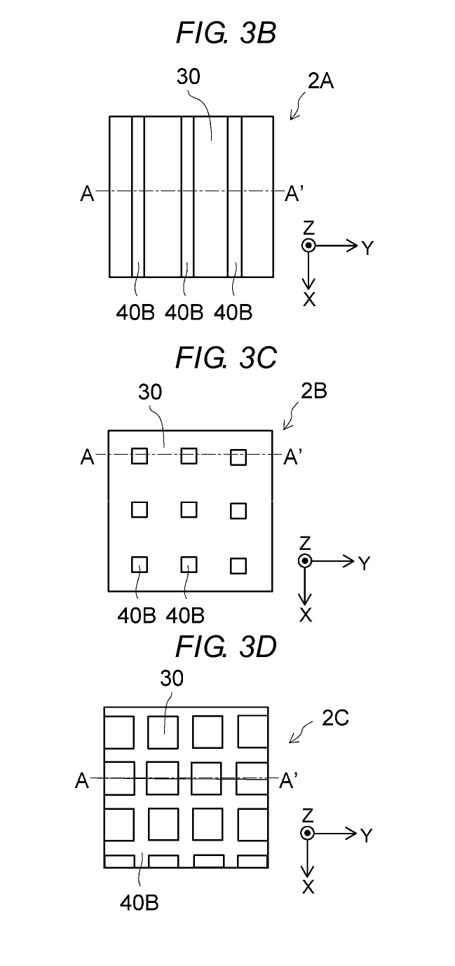

FIG. 3A is a schematic cross-sectional view illustrating a portion of a semiconductor device according to a second embodiment and taken along each line A-A′ of FIGS. 3B, 3C, and 3D, and FIGS. 3B, 3C, and 3D are schematic plan views along a cutting surface in line B-B′ of FIG. 3A viewed from above. Moreover, FIG. 3A corresponds to the region surrounded by the broken line P of FIG. 1A in which the first embodiment is illustrated. In the second embodiment, a cross-sectional view of the region is illustrated and features of the region are described.

In a semiconductor device 2 according to the second embodiment, a plurality of P⁺-type semiconductor regions 40B are provided below an insulating layer 70. The P⁺-type semiconductor region 40B includes a plurality of regions. For example, the plurality of regions are disposed at regular intervals in the Y direction of FIG. 3A. The semiconductor regions 40B come into contact with an N-type semiconductor region 30 and into contact with an insulating layer 70. For example, the semiconductor region 40B has a floating potential. Otherwise, a potential lower than the potential of a semiconductor region 30 may be applied to the semiconductor region 40B.

In the semiconductor device 2, a depletion layer DL2 is also formed by a diffusion potential caused by the junction between each of the P⁺-type semiconductor regions 40B and the N-type semiconductor region 30. An impurity concentration of the plurality of semiconductor regions 40B or an impurity concentration of the semiconductor region 30 is adjusted so as to connect depletion layers DL2 therebetween.

Thus, in a region A-1 in which the semiconductor region 40B is provided, a capacitance in which a parasitic capacitance C2 formed by the wiring layer 10/the insulating layer 70/the semiconductor region 40B and a junction capacitance C3 formed by the semiconductor region 40B/the depletion layer DL2/the semiconductor region 30 are connected in series becomes a part of the parasitic capacitance.

Here, a thickness of the depletion layer DL2 is adjusted so as to be larger than a thickness of the insulating layer 70. Thus, the parasitic capacitance C2 becomes smaller than the junction capacitance C3 and a parasitic capacitance C_{L} in which the parasitic capacitance C2 and the junction capacitance C3 are connected in series becomes C3 in which the capacitance is substantially small.

Furthermore, in a region A-2 interposed between the adjacent semiconductor regions 40B, a parasitic capacitance C4 is formed by the wiring layer 10/the insulating layer 70 and the depletion layer DL2/the semiconductor region 30. Here, a thickness d2 formed by adding the thickness of the insulating layer 70 and the thickness of the depletion layer DL2 is larger than a thickness d1 of the depletion layer DL2 formed below the semiconductor region 40B. Thus, the parasitic capacitance C4 in the region interposed between the adjacent semiconductor regions 40B is smaller than the parasitic capacitance C2.

As described above, also in the semiconductor device 2 according to the second embodiment, it is possible to decrease the parasitic capacitance of the semiconductor device without increasing the thickness of the insulating layer 70.

A plan view of the semiconductor region 40B cut at section B-B of FIG. 3A is illustrated in FIGS. 3B to 3D. For example, as illustrated in FIG. 3B, each of the plurality of semiconductor regions 40B extends in an X direction and may be disposed in a Y direction crossing the X direction. Furthermore, as illustrated in FIG. 3C, each of the plurality of semiconductor regions 40B may be disposed in a dot shape in the X direction and the Y direction. Furthermore, as illustrated in FIG. 3D, the semiconductor region 40B may be formed in a mesh shape.

### Third Embodiment

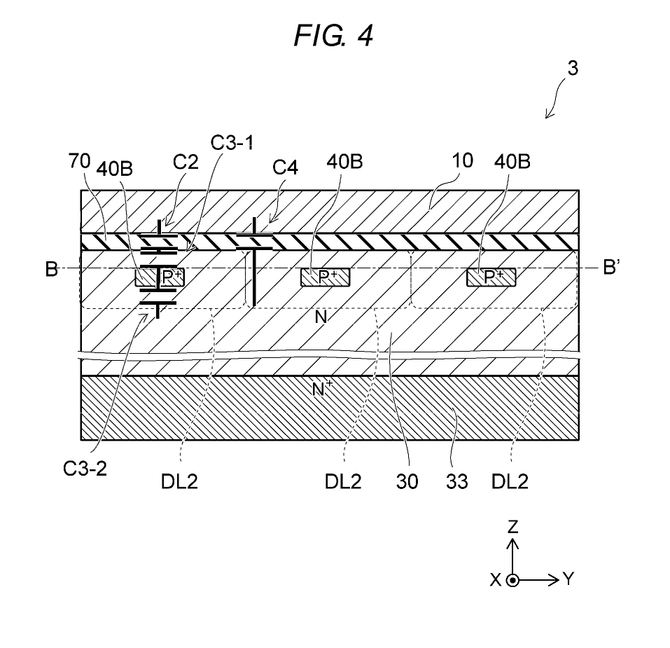

FIG. 4 is a schematic cross-sectional view illustrating a portion of a semiconductor device according to a third embodiment.

In a semiconductor device 3 according to the third embodiment, a plurality of P⁺-type semiconductor regions 40B are provided in an N-type semiconductor region 30. In such a structure, a depletion layer DL2 extends below the semiconductor region 40B and the depletion layer DL2 also extends above the semiconductor region 40B.

Thus, a junction capacitance C3 formed by junction between the semiconductor region 40B and a semiconductor region 30 becomes a capacitance in which a junction capacitance C3-1 and a junction capacitance C3-2 are connected in series. That is, the junction capacitance C3 of the semiconductor device 3 is further lowered than the junction capacitance C3 of the semiconductor device 2.

For example, a planar structure (a cutting surface in line B-B′ of FIG. 4) of the semiconductor region 40B according to the third embodiment may be the same structure as that illustrated in FIGS. 3B to 3D.

### Fourth Embodiment

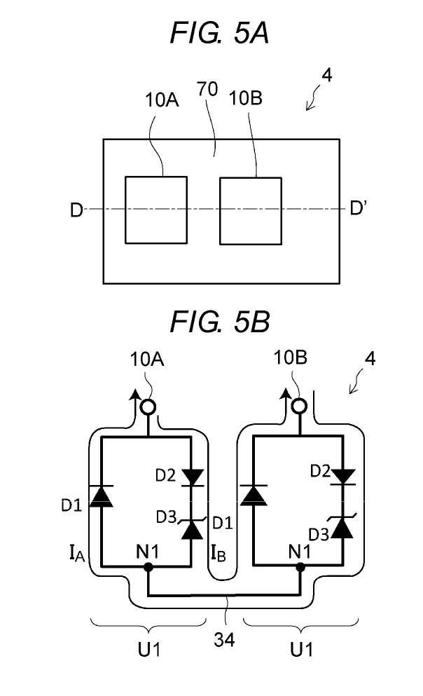

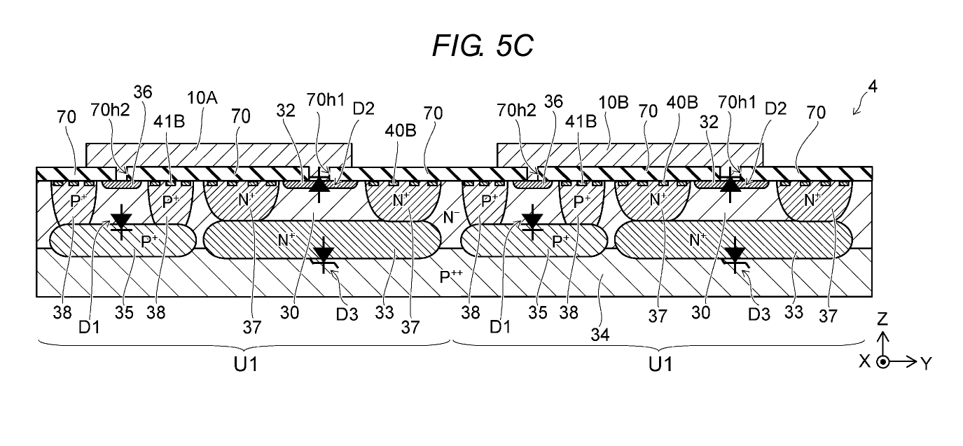

FIG. 5A is a schematic plan view illustrating a portion of a semiconductor device according to a fourth embodiment, FIG. 5B is an equivalent circuit diagram of the semiconductor device according to the fourth embodiment, and FIG. 5C is a schematic cross-sectional view illustrating a portion of the semiconductor device according to the fourth embodiment and illustrating a cross section taken along line D-D′ in FIG. 5A.

In a semiconductor device 4 according to the fourth embodiment, a wiring layer 10 is separated into a wiring layer 10A and a wiring layer 10B. For example, in the semiconductor device 4, as illustrated in FIGS. 5A and 5C, a part of a semiconductor region 30 is interposed between a P⁺⁺-type fourth semiconductor region (hereinafter, for example, a semiconductor region 34) and a semiconductor region 32. Here, the semiconductor region 34 is a semiconductor substrate. The semiconductor region 30 is epitaxially grown on the semiconductor region 34. A conductivity type of the semiconductor region 30 is an N⁻-type. The semiconductor region 32 comes into contact with the semiconductor region 30.

N⁺-type fifth semiconductor regions (hereinafter, for example, semiconductor regions 33) are selectively provided between the semiconductor region 30 and the semiconductor region 34. An impurity concentration of the semiconductor region 33 is higher than an impurity concentration of the semiconductor region 30. The semiconductor region 33 comes into contact with the semiconductor region 34.

P⁺-type sixth semiconductor regions (hereinafter, for example, semiconductor regions 35) are selectively provided between the semiconductor regions 30 and the semiconductor region 34. An impurity concentration of the semiconductor region 35 is lower than an impurity concentration of the semiconductor region 34. The semiconductor region 35 comes into contact with the semiconductor region 30.

Furthermore, in the semiconductor device 4, a part of the semiconductor region 30 is interposed between an N⁺-type seventh semiconductor region (hereinafter, for example, a semiconductor region 36) and the semiconductor region 35. An impurity concentration of the semiconductor region 36 is higher than an impurity concentration of the semiconductor region 30. The semiconductor region 36 is connected to the wiring layer 10A (or the wiring layer 10B) through a second opening (hereinafter, for example, an opening 70h2) provided in the insulating layer 70. The semiconductor region 36 comes into ohmic contact with the wiring layer 10A (or the wiring layer 10B).

Furthermore, in the semiconductor device 4, N⁺-type semiconductor regions 37 are provided on the semiconductor regions 33. The semiconductor region 37 comes into contact with the semiconductor region 30 on the semiconductor region 33. The semiconductor region 32 is surrounded by the semiconductor regions 37. The semiconductor region 37 comes into contact with the semiconductor region 33. Furthermore, in the semiconductor device 4, P⁺-type semiconductor regions are provided on the semiconductor regions 35. The semiconductor region 38 comes into contact with the semiconductor region 30 on the semiconductor region 35. The semiconductor region 36 is surrounded by the semiconductor regions 38. The semiconductor region 38 comes into contact with the semiconductor region 35. Moreover, the semiconductor regions 32, 33, 35, 36, 37, and 38 are formed by high acceleration ion implantation or epitaxial growth.

In the semiconductor device 4, a PN diode D1 is provided by the P⁺-type semiconductor region 35 and the N⁻-type semiconductor region 30. A PN diode D2 is provided by the P⁺-type semiconductor region 32 and the N⁻-type semiconductor region 30. A Zener diode D3 is provided by the P⁺⁺-type semiconductor region 34 and the N⁺-type semiconductor region 33. In the semiconductor device 4, a clover type circuit is configured with the PN diode D1, the PN diode D2, and the Zener diode D3.

In the semiconductor device 4, a region including the semiconductor regions 30, 32, 33, 35, 36, 37, and 38 provided on the semiconductor region 34 is repeated in the Y direction. That is, the semiconductor device 4 includes two sets of circuit units U1 having the PN diode D1, the PN diode D2, and the Zener diode D3. Nodes N1 of two sets of circuit units U1 are electrically connected to each other through the semiconductor region 34.

Thus, in the semiconductor device 4, if a positive transient voltage is applied, an excessive current flows through one of the wiring layer 10A and the wiring layer 10B as a current I_{A} or a current I_{B}. Meanwhile, if a negative transient voltage is applied, a direction of the excessive current is opposite to a direction of the current I_{A} or a direction of the current I_{B} in the drawing in one of the wiring layer 10A and the wiring layer 10B. That is, the semiconductor device 4 functions as an ESD protection diode.

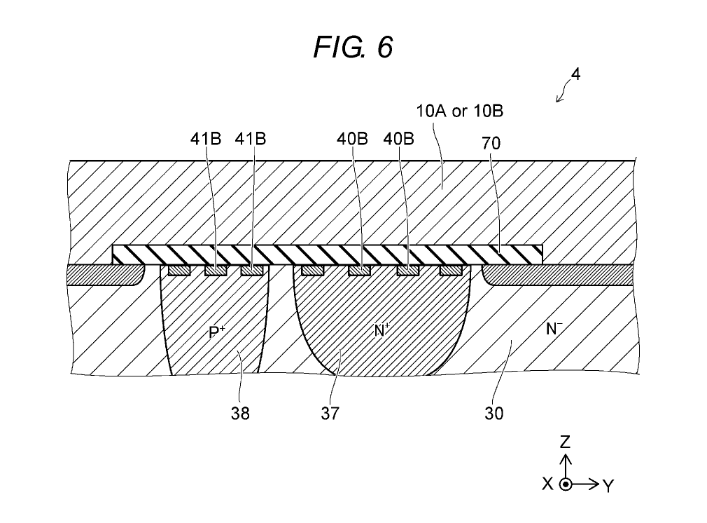

FIG. 6 is a schematic enlarged cross-sectional view illustrating a lower portion of an insulating layer of the semiconductor device according to the fourth embodiment.

In the semiconductor device 4, a plurality of P⁺-type semiconductor regions 40B are provided between the N⁺-type semiconductor region 37 and the insulating layer 70. The plurality of semiconductor regions 40B are provided below the insulating layer 70. The plurality of semiconductor regions 40B come into contact with the insulating layer 70.

Furthermore, in the semiconductor device 4, a plurality of N⁺-type semiconductor regions 41B are provided between the P⁺-type semiconductor region 38 and the insulating layer 70. The plurality of semiconductor regions 41B are provided below the insulating layer 70. The plurality of semiconductor regions 41B come into contact with the insulating layer 70.

In such a structure, the depletion layer DL2 is formed by the diffusion potential caused by the junction between the semiconductor region 40B and the semiconductor region 37. The depletion layer DL2 is formed by the diffusion potential caused by junction between the semiconductor region 41B and the semiconductor region 38. Thus, the parasitic capacitance of the semiconductor device 4 is further decreased than a case where the semiconductor regions 40B and 41B are not provided. Moreover, the semiconductor region 40B may be provided inside the semiconductor region 37 and the semiconductor region 41B may be provided inside the semiconductor region 38.

Furthermore, each of main components of the semiconductor regions described above is, for example, silicon (Si). Each of the main components of the semiconductor regions may be silicon carbide (SiC), gallium nitride (GaN), and the like. Furthermore, in the embodiment, unless otherwise specified, it is represented that the impurity concentration of the N-type (second conductivity type) is decreased in order of the N⁺-type, the N-type, the N⁻-type. In addition, it is represented that the impurity concentration of the P-type (first conductivity type) is decreased in order of the P⁺⁺-type, the P⁺-type, the P-type.

As an N-type dopant, for example, phosphorus (p), arsenic (As), and the like are used. As a P⁺-type and P-type dopant, for example, boron (B) and the like are used. Furthermore, in the semiconductor device according to the embodiment, it is possible to obtain the same effect even if the conductivity types of the P-type and the N-type are reversed.

For example, a material of the wiring layers 10, 10A, and 10B includes metal containing at least one from a group of aluminum (Al), titanium (Ti), nickel (Ni), tungsten (W), gold (Au), and the like. Furthermore, for example, a material of the insulating layer and the interlayer insulation film includes at least one of silicon oxide, silicon nitride, and the like.

In the embodiment described above, “on” in an expression that “a portion A is provided on a portion B” is used to mean a case where the portion A does not come into contact with the portion B and the portion A is provided above the portion B in addition to a case where the portion A comes into contact with the portion B and the portion A is provided on the portion B. Furthermore, “the portion A is provided on the portion B” may be applied to a case where the portion A and the portion Bare reversed and the portion A is positioned below the portion B, or a case where the portion A and the portion B are horizontally provided in the same line with each other. This is because the structure of the semiconductor device is not changed between before and after the rotation thereof even if the semiconductor device according to the embodiment is rotated.

Hitherto, the embodiments are described with reference to the specific examples. However, the embodiments are not limited to the specific examples. That is, one in which those skilled in the art apply appropriate design changes to those specific examples is included in the range of the embodiments as long as it includes the characteristics of the embodiments. Each element included in the specific examples and, a disposition, a material, a condition, a shape, a size thereof, and the like are not limited to those which are illustrated above and may be appropriately changed.

Furthermore, each of the elements included in each embodiment maybe combined as long as it is technically possible and the combination is included in the range of the embodiments as long as each of the elements includes the characteristics of the embodiments. In addition, in a category of the spirit of the embodiments, those skilled in the art may derive various modified examples and corrected examples, and the modified examples and the corrected examples are understood to be also included in the range of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor region of a first conductivity type;
a second semiconductor region of a second conductivity type selectively provided on a surface of the first semiconductor region;
an insulating layer over the first semiconductor region and the second semiconductor region, and having a first opening exposing a portion of the second semiconductor region therein;
a wiring layer on the insulating layer and electrically connected to the second semiconductor region through the first opening;
a third semiconductor region of the second conductivity type below the insulating layer and contacting the first semiconductor region;
a fourth semiconductor region of the second conductivity type, wherein the first semiconductor region is interposed between the fourth semiconductor region and the second semiconductor region;
a fifth semiconductor region of the first conductivity type between the first semiconductor region and the fourth semiconductor region, and having an impurity concentration higher than an impurity concentration of the first semiconductor region;
a sixth semiconductor region of the second conductivity type between the first semiconductor region and the fourth semiconductor region, and having an impurity concentration lower than an impurity concentration of the fourth semiconductor region; and
a seventh semiconductor region of the first conductivity type on the first semiconductor region, wherein the first semiconductor region is interposed between the sixth semiconductor region and the seventh semiconductor region, the seventh semiconductor region having an impurity concentration higher than the impurity concentration of the first semiconductor region, the seventh semiconductor region being connected to the wiring layer through a second opening in the insulating layer.

2. The device according to claim 1,
wherein the third semiconductor region includes a plurality of regions of the second conductivity type.

3. The device according to claim 2,
wherein the plurality of regions are in contact with the insulating layer.

4. The device according to claim 2,
wherein the plurality of regions are provided in the second semiconductor region.

5. The device according to claim 1,
wherein the third semiconductor region has a floating potential.

6. The semiconductor device according to claim 1, further comprising:
a first depletion layer adjacent to a junction between the second semiconductor region and the first semiconductor region.

7. The semiconductor device according to claim 6, further comprising:
a second depletion layer adjacent to the junction between the third semiconductor region and the first semiconductor region.

8. The semiconductor region of claim 7, wherein the first depletion layer extends across the opening in the insulating layer.

9. The device according to claim 8,
wherein the third semiconductor region includes a plurality of regions of the second conductivity type that are contact with the insulating layer.

10. The semiconductor device according to claim 1, wherein the third semiconductor layer contacts the side of the second semiconductor layer.

11. A semiconductor device, comprising:
a first semiconductor region of a first conductivity type;
a second semiconductor region of a second conductivity type selectively provided on a surface of the first semiconductor region;
an insulating layer over the first semiconductor region and the second semiconductor region, and having a first opening exposing a portion of the second semiconductor region therein;
a wiring layer on the insulating layer and electrically connected to the second semiconductor region through the first opening;
a first depletion layer in the first semiconductor region below the first opening; and
a second depletion layer in the first semiconductor region adjacent to the first depletion layer and spaced from the first opening.

12. The semiconductor device according to claim 11, wherein
the first depletion layer has a first capacitance;
the insulating layer has a second capacitance that is serial in series with respect to the first capacitance; and
the second depletion layer has a third capacitance that is parallel with respect to the first and second capacitances.

13. The semiconductor device of claim 11, further comprising a third semiconductor region interposed between the insulating layer and the first semiconductor region.

14. The semiconductor device of claim 13, wherein
the first depletion layer is formed at the junction of the first semiconductor layer and the second semiconductor layer; and
the second depletion layer is formed at the junction of the first semiconductor region and the third semiconductor region.

15. The semiconductor device of claim 14, wherein the thickness of the second depletion layer is thicker than the thickness of the insulation layer.

16. The semiconductor device of claim 13, wherein the third semiconductor region contacts the side of the second semiconductor layer.

17. A semiconductor device, comprising
a first semiconductor region of a first conductivity type;
a plurality of second semiconductor regions of a second conductivity type selectively provided in contact with the first semiconductor region;
an insulating layer over the first semiconductor region; and
a wiring layer provided on the insulating layer, wherein
the insulating layer has a first capacitance;
the second semiconductor regions have a second capacitance, and
a parasitic capacitance of the semiconductor device is equal to a parallel capacitance of the first capacitance and a third capacitance which is equal to a series capacitance of the first capacitance and the second capacitance.

18. The semiconductor device of claim 17, wherein the plurality of second semiconductor regions contact the insulating layer.

19. The semiconductor device of claim 17, wherein the plurality of second semiconductor regions are spaced from the insulating layer by an interposed portion of the first semiconductor region.

20. The semiconductor device of claim 17, wherein the plurality of second semiconductor regions are regularly spaced across the first semiconductor region.
